(19) United States
(12) Patent Application Publication
(10) Pub. No.: US 2025/0266797 A1
(43) Pub. Date: Aug. 21, 2025

(54) ADAPTIVE LOOP TO IMPROVE GAIN STAGE LINEARITY IN SERDES

(71) Applicant: QUALCOMM Incorporated, San Diego, CA (US)

(72) Inventors: Miao LI, San Diego, CA (US); Zhiqin CHEN, San Diego, CA (US); Chiu Keung TANG, San Diego, CA (US); Yu HUANG, San Diego, CA (US); Hongmei LIAO, San Diego, CA (US); Zhi ZHU, San Diego, CA (US)

(21) Appl. No.: 18/582,252

(22) Filed: Feb. 20, 2024

(51) Int. Cl. H03F 3/45; H03G 3/30

(52) U.S. Cl. CPC H03F 3/45224; H03G 3/30; H03G 2201/103

(57) ABSTRACT

A calibration circuit includes a replica transconductance stage that is a replica of a transconductance amplifier in a serializer/deserializer (SerDes) interface and a replica transimpedance stage that is a replica of a transimpedance amplifier in the SerDes interface. The replica transimpedance stage has an input coupled to its output. A comparison circuit is configured to generate a difference signal representative of a difference between voltage levels of an input signal received at an input of the replica transconductance stage and an output signal representative of voltage level at the output of the replica transimpedance stage. Replica feedback resistors are configured to couple an output of the replica transimpedance stage to the input of the replica transconductance stage. The difference signal can be used to select resistance values provided by the replica feedback resistors and by corresponding gain control resistors in the transimpedance amplifier in the SerDes interface.

### TECHNICAL FIELD

The present disclosure generally relates to high-speed data communication interfaces that use serializers and/or deserializers and, more particularly, to dynamic control of gm-TIA gain stages to ensure linearity in all expected operating conditions.

### BACKGROUND

Electronic device technologies have seen explosive growth over the past several years. For example, growth of cellular and wireless communication technologies has been fueled by better communications, hardware, larger networks, and more reliable protocols. Wireless service providers are now able to offer their customers an ever-expanding array of features and services, and provide users with unprecedented levels of access to information, resources, and communications. To keep pace with these service enhancements, mobile electronic devices (e.g., cellular phones, tablets, laptops, etc.) have become more powerful and complex than ever. Wireless devices may include a high speed bus interface for communication of signals between hardware components. For example, the high speed bus interface may be implemented using a Peripheral Component Interconnect Express (PCIe) bus. High frequency signals being communicated using the bus interface may experience attenuation. Therefore, circuits in the receiver may be used to equalize and amplify a signal received via the bus interface for processing. These equalizing and amplifying circuits are typically required to keep a relatively constant amplification or high linearity for a wide range of operating conditions.

### SUMMARY

Certain aspects of the disclosure relate to systems, apparatus, methods and techniques for dynamically calibrating gain in a high-frequency interface that includes a serializer/deserializer (SerDes). Dynamically calibrating gain can ensure linearity notwithstanding changes in process parameters, voltage and/or temperature.

In various aspects of the disclosure, a calibration circuit includes a replica transconductance stage that is a replica of a transconductance amplifier (“gm”) in a serializer/deserializer (SerDes) interface; a replica transimpedance stage that is a replica of a transimpedance amplifier (“TIA”) in the SerDes interface, the replica transimpedance stage having an input that is coupled to an output of the replica transimpedance stage; a comparison circuit configured to generate a difference signal representative of a difference between voltage levels of an input signal received at an input of the replica transconductance stage and an output signal representative of voltage level at the output of the replica transimpedance stage; and replica feedback resistors configured to couple an output of the replica transimpedance stage to the input of the replica transconductance stage.

In one aspect, the difference signal can be used to select resistance values provided by the replica feedback resistors and by corresponding gain control resistors in the transimpedance amplifier in the SerDes interface.

In various aspects of the disclosure, an apparatus includes a replica transconductance stage that is a replica of a transconductance amplifier (“gm”) in a serializer/deserializer (SerDes) interface; a replica transimpedance stage that is a replica of a transimpedance amplifier (“TIA”) in the SerDes interface, the replica transimpedance stage having an input that is coupled to an output of the replica transimpedance stage; means for comparing voltage levels, configured to generate a difference signal representative of a voltage difference between an input signal received at an input of the replica transconductance stage and an output signal representative of voltage level at the output of the replica transimpedance stage; and means for controlling gain of a gm-TIA gain stage that includes the transconductance amplifier and the transimpedance amplifier, including gain control resistors configured to couple outputs and inputs of the transimpedance amplifier, means for configuring replica feedback resistors that couple an output of the replica transimpedance stage to the input of the replica transconductance stage. The difference signal may be used by the means for configuring the replica feedback resistors to minimize or reduce the voltage difference between the input signal and the output signal.

In one aspect, the difference signal can be used by the means for controlling the gain of the gm-TIA gain stage by causing the gain control resistors to have the same resistance values as the replica feedback resistors.

In various aspects of the disclosure, a method for calibrating gain includes providing a DC input signal to an input of a replica transconductance stage that is a replica of a transconductance amplifier in a SerDes interface; coupling an output of the replica transconductance stage to an input of a replica transimpedance stage that is a replica of a transimpedance amplifier in the SerDes interface; generating a difference signal representative of a voltage difference between the DC input signal and output signal representative of voltage level at the output of the replica transimpedance stage; using the difference signal to minimize or reduce the voltage difference by configuring resistance values for replica feedback resistors that couple an output of the replica transimpedance stage to the input of the replica transconductance stage; and using the difference signal to configure gain control resistors in the transimpedance amplifier in the SerDes interface such that the gain control resistors have the same resistance values as the replica feedback resistors.

In one aspect, the gain control resistors are configured to control gain provided by the transimpedance amplifier in the SerDes interface. The gain control resistors may be configured to couple outputs and inputs of the transimpedance amplifier in the SerDes interface.

In one aspect, the voltage level at the input of the replica transconductance stage may be determined by a common mode voltage level at an input of the transconductance amplifier in the SerDes interface. The voltage level at the input of the replica transconductance stage is about 50 millivolts or less to mimic small-signal operation.

In certain aspects, the calibration circuit includes a multitap resistance bridge and one or more multiplexers. The multitap resistance bridge may be configured to receive a first signal from the output of the replica transimpedance stage. The one or more multiplexers may be configured to select between the first signal and one or more attenuated versions of the first signal provided by the multitap resistance bridge in order to provide the output signal representative of voltage level at the output of the replica transimpedance stage. The taps of the multitap resistance bridge may correspond to gain settings defined for a gm-TIA gain stage that includes the transconductance amplifier and the transimpedance amplifier.

### BRIEF DESCRIPTION OF THE DRAWINGS

FIG. 1 illustrates an example of a system-on-a-chip (SOC) in accordance with certain aspects of the present disclosure.

FIG. 2 illustrates an example of a data communication system that may be adapted in accordance with certain aspects of the present disclosure.

FIG. 3 illustrates certain aspects of a data communication interface that may be implemented in an SoC or in another IC device.

FIG. 4 illustrates an example of a transconductance-transimpedance gain stage that may be adapted or configured in accordance with certain aspects of the present disclosure.

FIG. 5 illustrates gain variations associated with process, voltage and temperature variances.

FIG. 6 illustrates an example of a transconductance-transimpedance gain stage that can be tuned using a linearity calibration loop configured in accordance with certain aspects of this disclosure.

FIG. 7 illustrates an example of a calibration circuit that is configured to implement a linearity calibration loop in accordance with certain aspects of this disclosure.

FIG. 8 illustrates an example of calibration results that can be expected from use of the calibration circuit illustrated in FIG. 7.

FIG. 9 is a flow diagram illustrating an example of a method for equalizing a signal received from a communication channel in accordance with certain aspects of the present disclosure.

### DETAILED DESCRIPTION

The detailed description set forth below in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well-known structures and components are shown in block diagram form in order to avoid obscuring such concepts.

With reference now to the Figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

The terms “computing device” and “mobile device” are used interchangeably herein to refer to any one or all of servers, personal computers, smartphones, cellular telephones, tablet computers, laptop computers, netbooks, ultrabooks, palm-top computers, personal data assistants (PDAs), wireless electronic mail receivers, multimedia Internet-enabled cellular telephones, Global Positioning System (GPS) receivers, wireless gaming controllers, and similar personal electronic devices which include a programmable processor. While the various aspects are particularly useful in mobile devices (e.g., smartphones, laptop computers, etc.), which have limited resources (e.g., processing power, battery, size, etc.), the aspects are generally useful in any computing device that may benefit from improved processor performance and reduced energy consumption.

The term “multicore processor” is used herein to refer to a single integrated circuit (IC) chip or chip package that contains two or more independent processing units or cores (e.g., CPU cores, etc.) configured to read and execute program instructions. The term “multiprocessor” is used herein to refer to a system or device that includes two or more processing units configured to read and execute program instructions.

The term “system on chip” (SoC) is used herein to refer to a single integrated circuit (IC) chip that contains multiple resources and/or processors integrated on a single substrate. A single SoC may contain circuitry for digital, analog, mixed-signal, and radio-frequency functions. A single SoC may also include any number of general purpose and/or specialized processors (digital signal processors (DSPs), modem processors, video processors, etc.), memory blocks (e.g., read only memory (ROM), random access memory (RAM), flash, etc.), and resources (e.g., timers, voltage regulators, oscillators, etc.), any or all of which may be included in one or more cores.

Memory technologies described herein may be suitable for storing instructions, programs, control signals, and/or data for use in or by a computer or other digital electronic device. Any references to terminology and/or technical details related to an individual type of memory, interface, standard, or memory technology are for illustrative purposes only, and not intended to limit the scope of the claims to a particular memory system or technology unless specifically recited in the claim language. Mobile computing device architectures have grown in complexity, and now commonly include multiple processor cores, SoCs, co-processors, functional modules including dedicated processors (e.g., communication modem chips, GPS receivers, etc.), complex memory systems, intricate electrical interconnections (e.g., buses and/or fabrics), and numerous other resources that execute complex and power intensive software applications (e.g., video streaming applications, etc.).

Process technology employed to manufacture semiconductor devices, including IC devices is continually improving. Process technology includes the manufacturing methods used to make IC devices and defines transistor size, operating voltages and switching speeds. Features that are constituent elements of circuits in an IC device may be referred as technology nodes and/or process nodes. The terms technology node, process node, process technology may be used to characterize a specific semiconductor manufacturing process and corresponding design rules. Faster and more power-efficient technology nodes are being continuously developed through the use of smaller feature size to produce smaller transistors that enable the manufacture of higher-density ICs.

Certain aspects of this disclosure relate to circuits used in a high-speed serializer-deserializer (SerDes). Circuits are described that can be deployed in the analog front-end (AFE) of a receiver. Certain aspects relate to components of the AFE gain stage, that may include equalizers such as a decision-feedback equalizer (DFE), a variable-gain amplifier (VGA), buffers, summers, and so on. In one example, some aspects of the disclosure relate to a VGA. Certain aspects relate to dynamically calibrating gain in a high-frequency interface that includes a serializer/deserializer (SerDes). Dynamically calibrating gain can ensure linearity notwithstanding changes in process parameters, voltage and/or temperature.

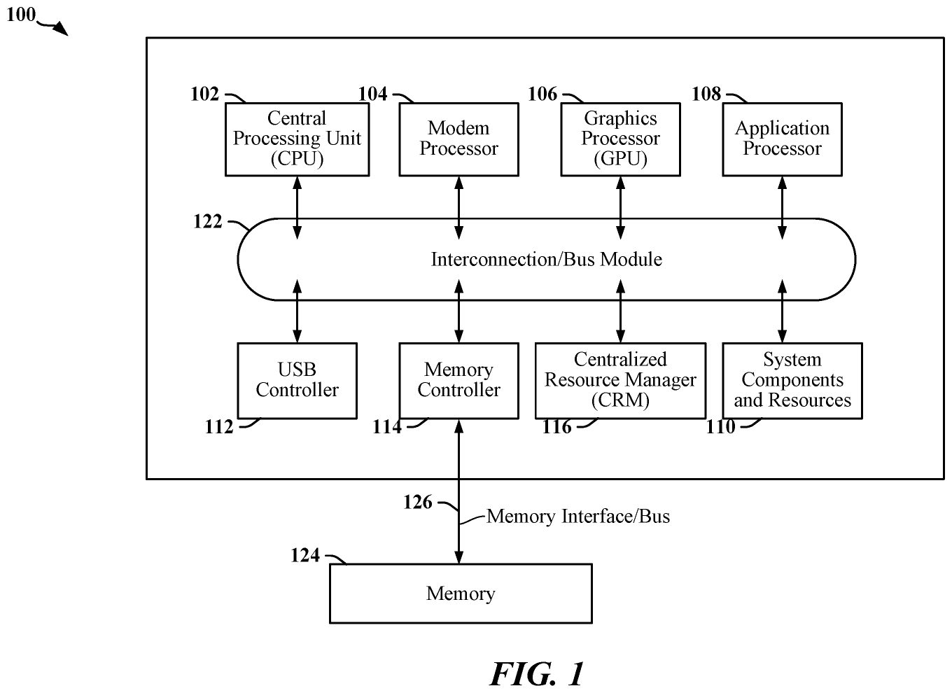

FIG. 1 illustrates example components and interconnections in a system-on-chip (SoC) 100 that may be suitable for implementing certain aspects of the present disclosure. The SoC 100 may include a number of heterogeneous processors, such as a central processing unit (CPU) 102, a modem processor 104, a graphics processor 106, and an application processor 108. Each processor 102, 104, 106, 108, may include one or more cores, and each processor/core may perform operations independent of the other processors/cores. The processors 102, 104, 106, 108 may be organized in close proximity to one another (e.g., on a single substrate, die, integrated chip, etc.) so that the processors may operate at a much higher frequency/clock rate than would be possible if the signals were to travel off-chip. The proximity of the cores may also allow for the sharing of on-chip memory and resources (e.g., voltage rails), as well as for more coordinated cooperation between cores.

The SoC 100 may include system components and resources 110 for managing sensor data, analog-to-digital conversions, and/or wireless data transmissions, and for performing other specialized operations (e.g., decoding high-definition video, video processing, etc.). System components and resources 110 may also include components such as voltage regulators, oscillators, phase-locked loops (PLLs), peripheral bridges, data controllers, system controllers, access ports, timers, and/or other similar components used to support the processors and software clients running on the computing device. The system components and resources 110 may also include circuitry for interfacing with peripheral devices, such as cameras, electronic displays, wireless communication devices, external memory chips, etc.

The SoC 100 may further include a Universal Serial Bus (USB) or other serial bus controller 112, one or more memory controllers 114, and a centralized resource manager (CRM) 116. The SoC 100 may also include an input/output module (not illustrated) for communicating with resources external to the SoC, each of which may be shared by two or more of the internal SoC components.

The processors 102, 104, 106, 108 may be interconnected to the USB controller 112, the memory controller 114, system components and resources 110, CRM 116, and/or other system components via an interconnection/bus module 122, which may include an array of reconfigurable logic gates and/or implement a bus architecture. Communications may also be provided by advanced interconnects, such as high performance networks on chip (NoCs).

The interconnection/bus module 122 may include or provide a bus mastering system configured to grant SoC components (e.g., processors, peripherals, etc.) exclusive control of the bus (e.g., to transfer data in burst mode, block transfer mode, etc.) for a set duration, number of operations, number of bytes, etc. In some cases, the interconnection/bus module 122 may implement an arbitration scheme to prevent multiple master components from attempting to drive the bus simultaneously. The memory controller 114 may be a specialized hardware module configured to manage the flow of data to and from a memory 124 via a memory interface/bus 126.

The memory controller 114 may comprise one or more processors configured to perform read and write operations with the memory 124. Examples of processors include microprocessors, microcontrollers, digital signal processors (DSPs), field programmable gate arrays (FPGAs), programmable logic devices (PLDs), state machines, gated logic, discrete hardware circuits, and other suitable hardware configured to perform the various functionality described throughout this disclosure. In certain aspects, the memory 124 may be part of the SoC 100.

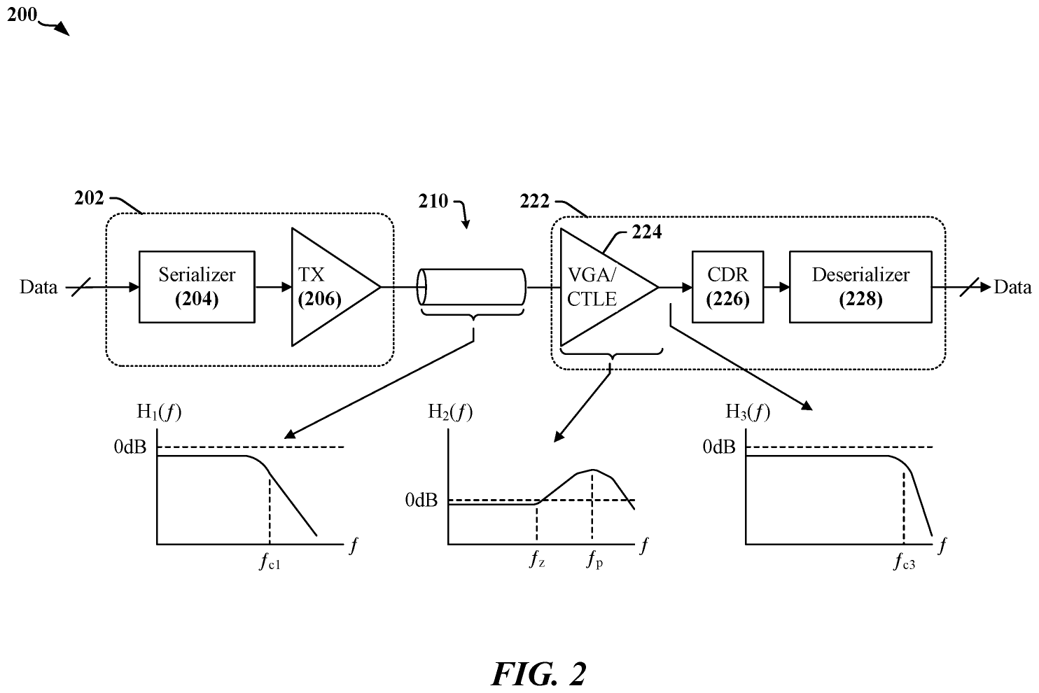

FIG. 2 illustrates an example of a data communication system 200 that may be adapted in accordance with certain aspects of the present disclosure. The data communication system 200 includes a transmitter 202, a data communication channel 210, and a receiver 222. The transmitter 202 may be provided in a first device that is configured to transmit a data signal to a second device. The data communication channel 210 provides a transmission medium through which the data signal propagates from the first device to the second device. The receiver 222 may be provided in the second device and may be configured to receive and process the data signal.

In one example, the transmitter 202 includes a serializer 204 configured to convert parallel data into serial data. The transmitter 202 further includes a transmit driver 206 configured to generate a data signal based on the serial data for transmission to the receiver 222 through the data communication channel 210.

The data communication channel 210 may be implemented using any type of transmission medium by which a data signal can propagate from the transmitter 202 to the receiver 222. Examples of the data communication channel 210 includes one or more metallization traces (which may include one or more vias) on a printed circuit board (PCB), stripline, microstrip, coaxial cable, twisted pair, etc.

In the illustrated example, the receiver 222 includes a VGA with a continuous time linear equalizer (CTLE), a clock data recovery circuit (the CDR 226) and a deserializer 228. The combination of the VGA and CTLE is referenced herein as the VGA/CTLE 224. CTLE may refer to techniques for boosting the higher frequency components of the signal at the receiver in order to bring all frequency components of the signal to a similar amplitude ratio before channel attenuation, improving jitter and eye-diagram performance. As disclosed herein, the VGA/CTLE 224 is configured to perform equalization and amplification of the received data signal. The CDR 226 is configured to recover a clock associated with the data signal and use the clock to recover the serial data from the data signal. The deserializer 228 is configured to convert the serial data back into parallel data.

The data communication channel 210 typically has a frequency response H₁(f) that is similar to a low pass filter. For instance, the frequency response H₁(f) has relatively low losses from direct current (DC) up to a particularly cutoff frequency f_{c1}; then the losses increase monotonically above the cutoff frequency f_{c1}. The frequency response H₁(f) of the data communication channel 210 limits the data rate at which data may be sent through the channel. For example, the cutoff frequency f_{c1} should be at least to the Nyquist rate of the data signal. If the Nyquist rate of the data signal is above the cutoff frequency f_{c1}, the data signal exhibits distortion at the receiver 222, which may be characterized as the eye in a signal eye diagram closing or getting smaller, making it difficult to recover the clock and the data by the CDR 226.

The VGA/CTLE 224 may perform equalization and amplification to increase the high frequency components of the data signal in order to increase the data rate at which the data signal may be sent through the data communication cable and reliably recovered at the receiver 222. For example, the VGA/CTLE 224 may be configured to provide a frequency response H₂(f) that is substantially flat from DC up to a frequency f_{z} corresponding to a Zero. Then, above the zero frequency f_{z}, the frequency response H₂(f) of the VGA/CTLE 224 increases up to a frequency fₚ corresponding to a pole. Above the pole frequency fₚ, the frequency response H₂(f) of the VGA/CTLE 224 decreases monotonically. In some examples, the VGA/CTLE 224 may have more than one pole and one zero.

The VGA/CTLE 224 may be configured to have a frequency response H₂(f) where the pole frequency fₚ substantially coincides with the cutoff frequency f_{c1} of the frequency response H₁(f) of the data communication channel 210. As the data communication channel 210 is cascaded with the VGA/CTLE 224, the frequency responses H₁(f) and H₂(f) of the data communication channel 210 and the VGA/CTLE 224 combine at the output of the VGA/CTLE 224 to form a composite frequency response H₃(f). Thus, the high frequency boost at the pole frequency fₚ of the VGA/CTLE frequency response H₂(f) compensates for the loss roll off at the cutoff frequency f_{c1} of the channel frequency response H₁(f) to generate the composite frequency response H₃(f) having a cutoff frequency f_{c3} much higher than the cutoff frequency f_{c1} of the channel frequency response H₁(f). Thus, through the use of the VGA/CTLE 224, much higher data rates between the transmitter 202 and receiver 222 may be realized.

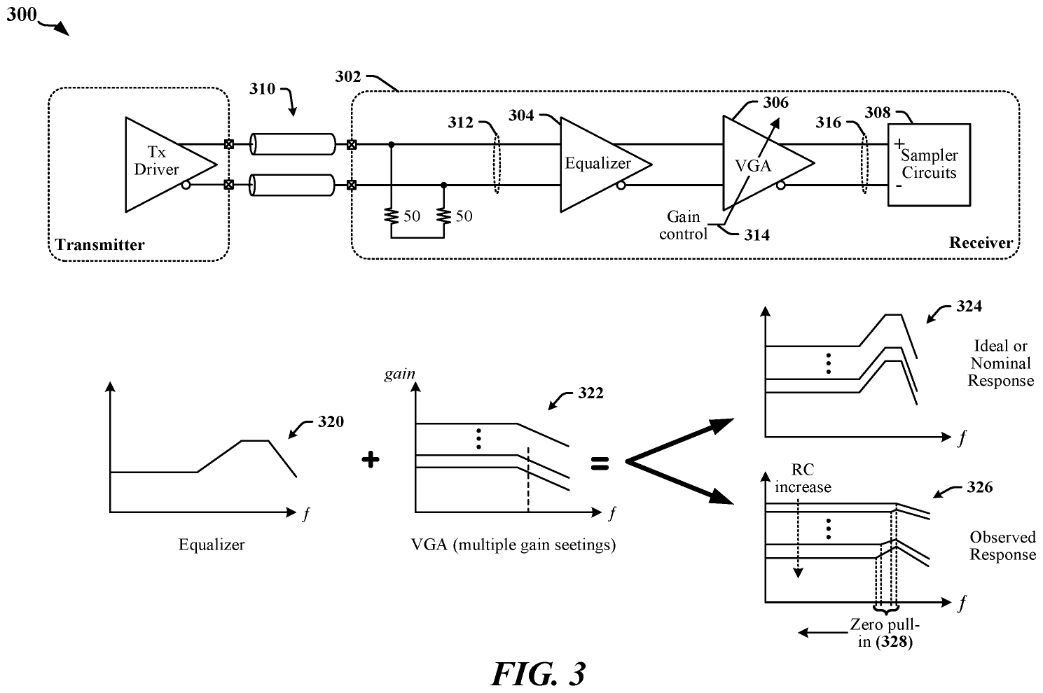

FIG. 3 illustrates certain effects of manufacturing process, voltage or temperature (PVT) variations affect the operation of transistors and other components in a data communication interface 300. The illustrated data communication interface 300 may be implemented in an SoC or in another IC device. The receiver 302 in the data communication interface 300 includes differential signal processing circuits, including an equalizer 304 and a variable gain amplifier 306. The differential signal processing circuits can be configured to generate a differential output signal 316 by applying a frequency-dependent gain to a differential input signal 312, which is received from a differential communication channel 310 in the illustrated example. The differential output signal 316 may be provided to sampler circuits 308 configured to extract data and other information transmitted over the communication channel 310. In one example, the differential input signal 312 is applied to gate inputs or other control inputs of a pair of input transistors in the equalizer 304 and the output of the equalizer 304 is provided to the VGA 306. The gain of the VGA 306 is configurable through a gain control input 314. In one example, the gain control input 314 may include a 4-bit binary value that selects a gain setting from among 16 possible settings.

In the receiver 302, the VGA 306 cooperates with the equalizer 304 to equalize and amplify a small differential input signal 312 to a level that can be processed by a next stage. Ideally, the frequency response 320 of the equalizer 304 and the frequency response 322 of the VGA 306 produce an ideal combined frequency response 324 for each gain setting of the VGA 306. In the ideal situation the responses are substantially parallel for multiple gain settings in the combined frequency response 324. Parallel responses are indicative of consistent frequency response regardless of gain setting. A consistent equalization frequency response is typically desired regardless of the gain configured for the VGA 306. For example, the same equalization frequency response is typically desired for low amplitude signals and high amplitude signals, including when different gain settings are configured for the two signals.

In conventional systems, maintaining parallel responses for the different VGA gain settings can be very challenging. In many conventional systems, changes in VGA gain can affect equalizer pole/zero locations at high data rates. An observed combined frequency response 326 illustrates a loss of consistency between the different VGA gain settings that is indicated by a loss of parallelism at higher frequencies. In some instances, changes in the VGA 306 can affect the location of a parasitic-related Zero in the frequency response 326, in a manner referred to herein as “Zero pull-in” 328.

In high speed SerDes design, gain stage linearity plays critical role in signal processing. In one example, the use of four-level pulse-amplitude modulation (PAM-4) can be severely compromised by sub optimal gain stage linearity. PAM-4 may be used to increase data transmission rates without increasing the signaling rate over a communication link. PAM-4 increases the data rate through the use of four signal levels to enable two bits to be transmitted in a single bit transmission interval. A failure to meet gain stage linearity specifications in a PAM-4 system can result in severe distortions in transitions between four-level signal swings. Complying with gain stage linearity requires the gain stage to maintain a substantially constant amplification and/or high linearity over PVT corners. PVT corners may be defined by manufacturing tolerances (process corners) and by different voltage or temperature limits defined for circuits includes in the SerDes interface.

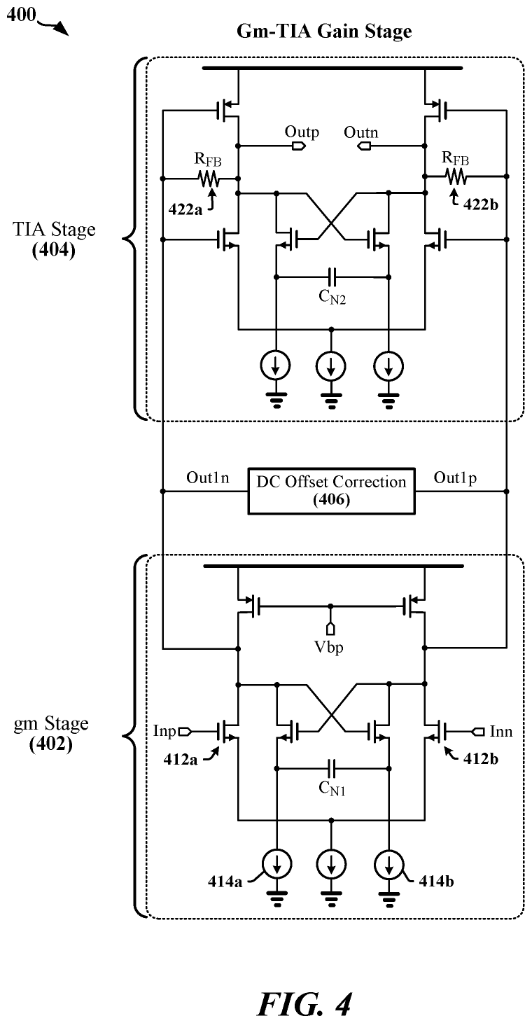

FIG. 4 illustrates an example of a Gₘ-TIA circuit 400 comprising a transconductance amplifier stage (the Gₘ stage 402) and a transimpedance amplifier stage (“the TIA stage 404”). The Gₘ-TIA circuit 400 is used in certain ultra-high speed SerDes interfaces due to its ability to provide high gain and support high bandwidth signaling in a SerDes interface.

In some implementations, the Gₘ-TIA circuit 400 may be configured or operated as a VGA. The Gₘ-TIA circuit 400 includes a pair of input transistors 412a, 412b (the Gₘ pair) and corresponding tail circuits 414a, 414b. In some instances, the input transistors 412a, 412b may be formed as n-type metal-oxide-semiconductor field effect transistors (NMOS FETs).

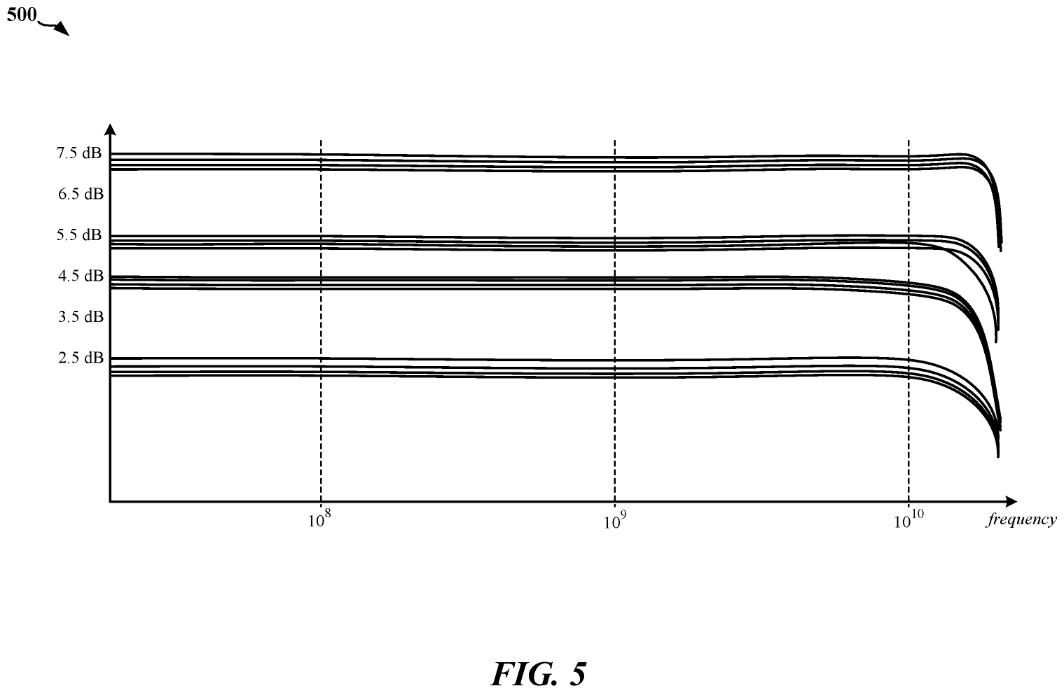

The gain of the Gₘ-TIA circuit 400 can vary greatly over various PVT corners. An example of gain dispersion 500 over the PVT corners associated with the Gₘ-TIA circuit 400 is illustrated in FIG. 5. The level of gain variations can be attributed to the combined number of PVT corners associated with the Gₘ stage 402, the TIA stage 404 and other circuits, such as the direct current (DC) offset correction circuit 406 provided in the illustrated example. Transconductance and transimpedance varies with PVT variances.

Conventional circuits use a “constant GₘR” technique to tune the product of transconductance and load resistance to a relatively constant value over a defined range of PVT variances or corners. The conventional gain stage is implemented using current-mode logic (CML) circuits. CML circuit gain is quite straightforward, and may be represented as Gₘ*R_{L}, where R_{L} is the output loading resistance. In these circuits, the current source may be tuned to tune Gₘ to a relatively constant value over PVT.

In the ideal or nominal case, the gain of the Gₘ-TIA circuit 400 can be stated as Gₘ*R_{FB}, where the term R_{FB} represents the resistance of the feedback resistors 422a, 422b. Accordingly, it would appear that the constant GₘR technique can be used to tune the gain. The gain variations illustrated in FIG. 5 may shrink somewhat, many other variations in gain remain over defined PVT corners. These other variations in gain may derive from the relationship between the gain of the TIA stage 404 and the gₘ of the PMOS and/or NMOS transistors used to implement the Gₘ-TIA circuit 400, as well as the output impedance of the PMOS and/or NMOS transistors. Variations in gₘ and output impedance of the PMOS and/or NMOS transistors can contribute to variations in the gain of the Gₘ-TIA circuit 400 over PVT corners.

Certain aspects of this disclosure provide circuits and techniques that can adaptively maintain a constant gain obtained from a Gₘ-TIA circuit over defined PVT corners. Certain aspects of this disclosure provide a capability to adaptively tune the gain to multiple PVT corners. In certain implementations, a linearity calibration loop is employed to counteract gain variations. The linearity calibration loop may be used to tune the gain to pre-defined values, such as 0 dB, 3.5 dB and/or 6 dB.

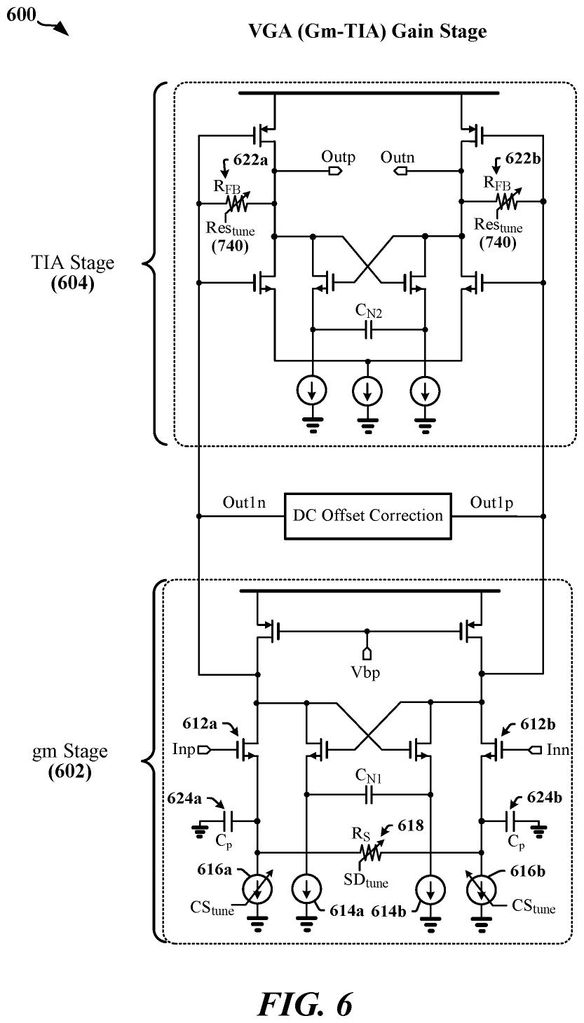

FIG. 6 illustrates an example of a Gₘ-TIA circuit 600 that can be tuned using a linearity calibration loop configured in accordance with certain aspects of this disclosure. The Gₘ-TIA circuit 600 corresponds in some respects to the Gₘ-TIA circuit 400 illustrated in FIG. 4. The Gₘ-TIA circuit 600 includes a Gₘ stage 602 and a TIA stage 604. The gₘ-TIA circuit 600 includes a pair of input transistors 612a, 612b (the Gₘ pair) and corresponding tail circuits 614a, 614b. In some implementations, the input transistors 612a, 612b may be formed as NMOS FETs. The input transistors 612a, 612b may alternatively be implemented using p-type metal-oxide-semiconductor field effect transistors (PMOS FETs).

The Gₘ stage 602 includes a source degeneration resistor 618 (generally a resistive device) that couple the sources of the input transistors 612a, 612b. The value of the source degeneration resistor 618 may be controlled directly or indirectly by the linearity calibration loop. In one example, the resistance value of the source degeneration resistor 618 may be configured by a 16-bit word. The resistance value of the source degeneration resistor 618 controls the gain of the Gₘ-TIA circuit 600. In various examples, the 16-bit word may be encoded using binary or unary encoding. Unary encoding, which may be referred to as thermometer encoding, represents data in the quantity of bits set to ‘1’ that precede a terminating ‘0’, or the quantity of bits set to ‘0’ that precede a terminating ‘1’. Parasitic capacitance is represented by parasitic capacitors 624a, 624b (Cₚ) coupled to the sources of the input transistors 612a, 612b, respectively.

A linearity calibration loop provided according to certain aspects of this disclosure may be configured to obtain a constant gain from a Gₘ-TIA circuit 600 by tuning the TIA resistance value (R_{FB}) of the feedback resistances 622a, 622b in the TIA stage 604. Transimpedance of the TIA stage 604 is linearly proportional to REB when the current sources in the TIA stage 604 source or sink a fixed current value. Gain of the Gₘ-TIA circuit 600 is linearly proportional to the transimpedance. In one aspect of this disclosure, gain of the Gₘ-TIA circuit 600 can be directly and/or linearly tuned by tuning R_{FB}.

The gain of the Gₘ-TIA circuit 600 can also be tuned by controlling current sources 616a, 616b or the resistance value (Rs) of the source degeneration resistor 618 in the Gₘ stage 602. These methods involve non-linear relationships between the controlled parameter and the gain of the Gₘ-TIA circuit 600. Gₘ is square root proportional to current and control of gain of the Gₘ-TIA circuit 600 requires a large current tuning range for current sources 616a, 616b. Controlling the gain of the Gₘ-TIA circuit 600 through tuning the source degeneration resistor 618 involves tuning an inverse value. The differential pair transconductance Gₘ may be stated as:

$${G}_{m} = ( \frac{gm}{1 + gm * Rs} ) ,$$

where gₘ represents the transconductance gain of the input transistors 612a, 612b and Rs represents the resistance of the source degeneration resistor 618. Absent the effect of the parasitic capacitors 624a, 624b, VGA gain can be linearly tuned by changing Rs. However, the capacitive contribution (Cs) at the sources of the input transistors 612a, 612b creates a Zero (Rs*Cs). When Rs is small, this Zero is not an issue since it is close to output Pole and is suppressed. When Rs increases, VGA high-frequency gain is boosted at Zero frequency due to Zero pull-in. An example of Zero pull-in 328 is illustrated in FIG. 3.

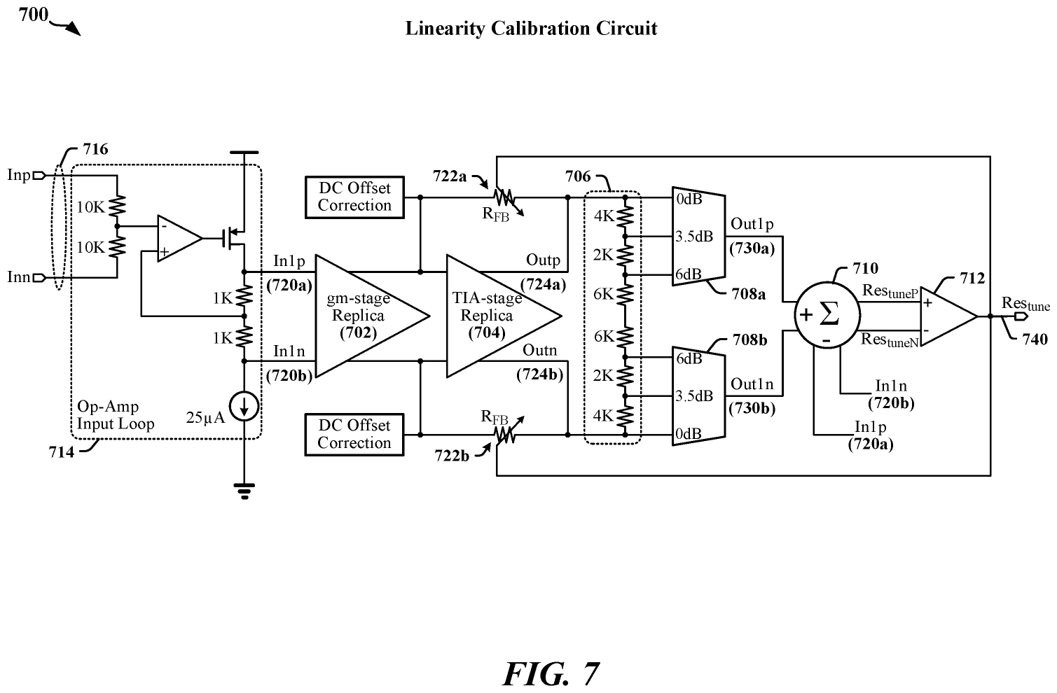

FIG. 7 illustrates an example of a calibration circuit 700 that is configured to implement a linearity calibration loop in accordance with certain aspects of this disclosure. In the illustrated example, the calibration circuit 700 is configured to control the value of the feedback resistances 622a, 622b in the TIA stage 604. The calibration circuit 700 can adaptively obtain a constant gain from the Gₘ-TIA circuit 600 over multiple PVT corners.

In one aspect the calibration circuit 700 mimics certain aspects of the operation of the Gₘ-TIA circuit 600. Small DC signal gain is used to simulate outcomes that may be applicable to alternating current (AC) signals processed by the Gₘ-TIA circuit 600. The calibration circuit 700 includes a replica Gₘ stage 702 and a replica TIA stage 704. The replica Gₘ stage 702 is nominally or ideally identical to the Gₘ stage 602 in the Gₘ-TIA circuit 600 and the replica TIA stage 704 is nominally or ideally identical to the TIA stage 604 in the Gₘ-TIA circuit 600. The calibration circuit 700 includes a feedback loop that is configured to cause a differential output signal, which comprises the Out1p signal 730a and the Out In signal 730b, to have the same voltage levels as a differential input signal that comprises the In1p signal 720a and the In1n signal 720b.

The differential input signal is a DC signal provided to the replica Gₘ stage 702 by an operational amplifier input circuit (i.e., the Op Amp input loop 714). The Op Amp input loop 714 is configured to receive the differential signal 716 provided to the input transistors 612a, 612b of the Gₘ stage 602 in the Gₘ-TIA circuit 600, and to generate the differential input signal provided to the replica Gₘ stage 702 such that the In1p signal 720a and the In1n signal 720b have a common-mode voltage that is equal to the common mode voltage of the differential signal 716 provided to the input transistors 612a, 612b of the Gₘ stage 602. In the illustrated example, the In1p signal 720a and the In1n signal 720b are limited to a 50 millivolt (mV) maximum amplitude.

The In1p signal 720a and the In1n signal 720b drive the replica Gₘ stage 702, which drives the replica TIA stage 704. Feedback resistances 722a, 722b couple each of the complementary outputs of the replica TIA stage 704 to a respective complementary input to the replica TIA stage 704. The resistance value configured for the feedback resistances 722a, 722b controls transimpedance and thereby controls gain. The resistance values configured for the feedback resistances 722a, 722b are modified when the Out1p signal 730a and the Out In signal 730b have different voltage levels than the In1p signal 720a and the In1n signal 720b. The resistance values of the feedback resistances 722a, 722b are modified in a manner that causes the voltage levels of the Out1p signal 730a and the Out In signal 730b to converge on the voltage levels of the In1p signal 720a and the In1n signal 720b.

The Out1p signal 730a and the Out In signal 730b are derived from the output of the replica TIA stage 704. The output of the replica TIA stage 704 includes a complementary signal pair comprising the Outp signal 724a and the Outn signal 724b that are coupled to one another through a multi-tap resistance ladder 706. The multi-tap resistance ladder 706 may also be referred to as a multitap resistance bridge. The multi-tap resistance ladder 706 realizes a voltage divider function between the Outp signal 724a and the Outn signal 724b. The multi-tap resistance ladder 706 provides multiple versions of the Outp signal 724a and the Outn signal 724b that are differentiated by the degree of attenuation applied through the multi-tap resistance ladder 706. The multi-tap resistance ladder 706 provides multiple versions of the Outp signal 724a and the Outn signal 724b to respective multiplexers 708a, 708b. In the illustrated example, the multiplexers 708a, 708b receive three versions of the Outp signal 724a and the Outn signal 724b, including a 0 dB (unattenuated), 3.5 dB and 6 dB versions of the Outp signal 724a and the Outn signal 724b. The multiplexers 708a, 708b provide the Out1p signal 730a and the Out1n signal 730b. The multiplexers 708a, 708b can be used to tune the Gₘ-TIA circuit 600 for multiple gain values.

The output of the multiplexers 708a, 708b is used to determine the resistance values of the feedback resistances 722a, 722b and thereby control the gain of the Gₘ-TIA circuit 600. A summer 710 compares the voltage levels of the Out1p signal 730a and the Out1n signal 730b with the voltage levels of the In1p signal 720a and the In1n signal 720b. In the illustrated example, the summer 710 compares the voltage levels by subtraction. The differential output of the summer 710 is converted to a form that can be used to select or adjust the resistance values of the feedback resistances 722a, 722b in order to reduce the difference in voltage between the Out1p signal 730a and the Out In signal 730b and the In1p signal 720a and the In1n signal 720b. In one example, a differential comparator 712 produces an analog or digital output signal (Resₜᵤₙₑ 740) that indicates whether the resistance values of the feedback resistances 722a, 722b should be increased or decreased. In some instances, Resₜᵤₙₑ 740 indicates an amount of change to be applied to the resistance values of the feedback resistances 722a, 722b. The target or final result to be acquired by the calibration circuit 700 is reached when the inputs to the differential comparator 712 are equal. In some implementations, the resistance values of the feedback resistances 722a, 722b and the feedback resistances 622a, 622b in the TIA stage 604 can be directly controlled by Resₜᵤₙₑ 740. In one example, the calibration circuit 700 includes control logic, analog-to-digital converters, counters, registers and/or other circuits that provide Resₜᵤₙₑ 740 as a digital output signal that selects the resistance values of the feedback resistances 722a, 722b.

In certain implementations, Resₜᵤₙₑ 740 may be used to select or adjust the resistance values of the feedback resistances 622a, 622b in the TIA stage 604 of a Gₘ-TIA circuit 600 illustrated in FIG. 6. In these implementations, the resistance values of feedback resistances 622a, 622b track resistance values of feedback resistances 722a, 722b in the calibration circuit 700. Each of the feedback resistances 622a, 622b, 722a, 722b may include a resistor array that includes switches that can be used to configure the resistance value provided by the resistor array. In one example, a combination of switches may be enabled in order to couple some combination of resistors in parallel. In some implementations, the codeword may encode a value using binary or unary encoding. Unary encoding, which may be referred to as thermometer encoding, represents data in the quantity of bits set to ‘1’ that precede a terminating ‘0’, or in the quantity of bits set to ‘0’ that precede a terminating ‘1’. The use of thermometer encoding and other such encoding can accelerate selection of resistance value provided by the resistor array. In some implementations, the codeword may be selected based on the state or value of Resₜᵤₙₑ 740. In some implementations, the codeword may be selectively adjusted, that is increased, decreased or maintained, based on a change in state or value of Resₜᵤₙₑ 740. Each of the resistor arrays used to implement feedback resistances 622a, 622b, 722a, 722b may include or be coupled to control logic, analog-to-digital converters, counters, registers or other circuits that respond to Resₜᵤₙₑ 740 by selecting the codeword used to activate a combination of switches that obtains a desired or indicated resistance value to be provided by the resistor array.

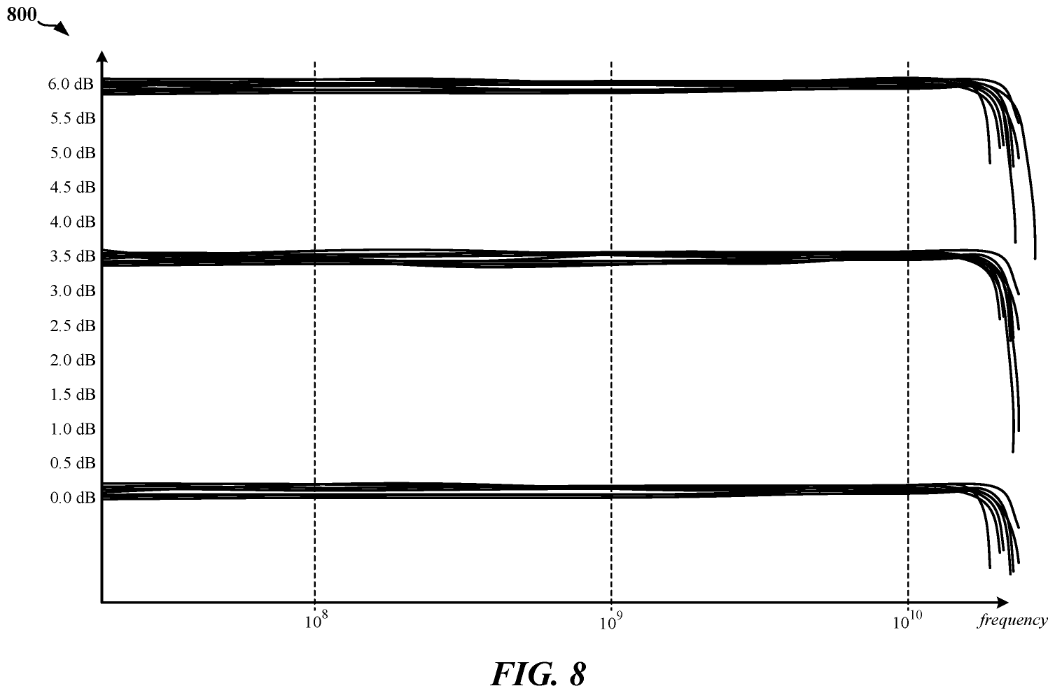

FIG. 8 illustrates an example of calibration results 800 that can be expected from use of the calibration circuit 700. The illustrated calibration results 800 relate to calibration procedures that are performed in the presence of PVT variations. The illustrated calibration results 800 are obtained using a multi-tap resistance ladder 706 that provides 0 dB, 3.5 dB and 6 dB versions of the replica TIA stage 704. The illustrated calibration results 800 correspond to a Gₘ-TIA circuit 600 gain that is calibrated to 0 dB, 3.5 dB, and 6 dB. In one example, gain variation for 33 PVT corners is less than 1 dB. The 1 dB attenuation frequency is typically greater than 17 GHZ.

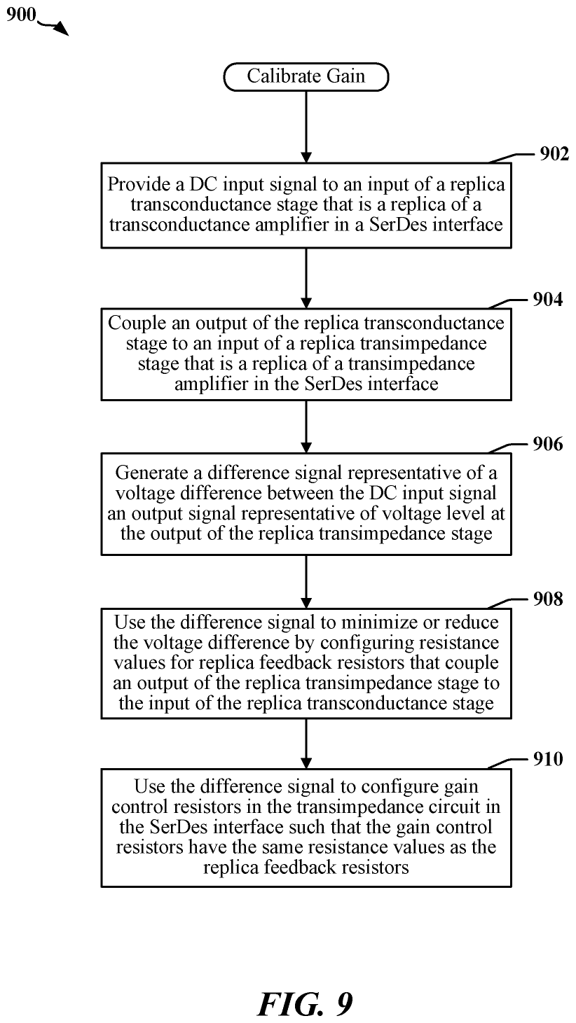

FIG. 9 is a flow diagram illustrating an example of a method 900 for calibrating gain in a high speed SerDes interface. In one example, the gain of a gₘ-TIA gain stage may be dynamically calibrated in order to counteract gain variations attributable to PVT variances. The method 900 implements a linearity calibration loop that can tune the gain to pre-defined values. In one example, the method 900 can tune for gains of 0 dB, 3.5 dB, and/or 6 dB in a gₘ-TIA gain stage that provides selectable gain. In one example, the gₘ-TIA gain stage can operate as a variable gain amplifier. In other examples, the gₘ-TIA gain stage can operate as a low-frequency or high-frequency equalizer.

At block 902, a DC input signal may be provided to an input of a replica transconductance stage. The replica transconductance stage may be a replica of a transconductance amplifier (i.e., a transconductance stage or circuit in a SerDes interface. At block 904, an output of the replica transconductance stage may be coupled to an input of a replica transimpedance stage. The replica transimpedance stage may be a replica of a transimpedance amplifier in the SerDes interface.

At block 906, a difference signal may be generated. The difference signal may be representative of a voltage difference between the DC input signal an output signal representative of voltage level at the output of the replica transimpedance stage. At block 908, the difference signal may be used to minimize or reduce the voltage difference between the DC input signal an output signal. The voltage difference may be minimized or reduced by configuring resistance values for replica feedback resistors that couple an output of the replica transimpedance stage to the input of the replica transconductance stage.

At block 910, the difference signal may be used to configure gain control resistors in the transimpedance amplifier in the SerDes interface. The difference signal may cause the gain control resistors to have the same resistance values as the replica feedback resistors. The gain control resistors may be configured to control the gain of the transimpedance amplifier in the SerDes interface. The gain control resistors may be configured to couple outputs and inputs of the transimpedance amplifier in the SerDes interface.

In certain implementations, the voltage level at the input of the replica transconductance stage is determined by a common mode voltage level at an input of the transconductance amplifier in the SerDes interface. In some examples, the voltage level at the input of the replica transconductance stage is about 50 millivolts or less.

In certain implementations, a first signal received from the output of the replica transimpedance stage may be attenuated to obtain one or more attenuated versions of the first signal. The output signal that is representative of voltage level at the output of the replica transimpedance stage may be provided by selecting between the first signal and the one or more attenuated versions of the first signal. In some implementations, the first signal is attenuated using a multitap resistance bridge. The taps of the multitap resistance bridge may be selected to correspond or define the gain settings for a gₘ-TIA gain stage that includes the transconductance amplifier and the transimpedance amplifier. In some implementations, one or more multiplexers are used to select between the first signal and the one or more attenuated versions of the first signal.

The operational steps described in any of the exemplary aspects herein are described to provide a subset of examples of possible implementations. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flow diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The various operations of methods described above may be performed by any suitable means capable of performing the corresponding functions. The means may include various hardware and/or software component(s) and/or module(s), including, but not limited to a circuit, an application-specific integrated circuit (ASIC), or processor. Generally, where there are operations illustrated in figures, those operations may have corresponding counterpart means-plus-function components with similar numbering.

In certain aspects, means for comparing voltage levels may include the summer 710 and the differential comparator 712 illustrated in FIG. 7, and the means for controlling gain of a gₘ-TIA gain stage that includes the transconductance amplifier and the transimpedance amplifier includes the feedback resistances 622a, 622b illustrated in FIG. 6. The means for obtaining one or more attenuated versions of a first signal received from the output of the replica transimpedance stage may include the multi-tap resistance ladder 706 illustrated in FIG. 7, and the means for selecting between the first signal and the one or more attenuated versions of the first signal may include the multiplexers 708a, 708b illustrated in FIG. 7.

In one example, a calibration circuit provided in accordance with certain aspects of this disclosure has a replica transconductance stage and a replica transimpedance stage. The replica transconductance stage may be a replica of a transconductance amplifier in a SerDes interface. The replica transimpedance stage may be a replica of a transimpedance amplifier in the SerDes interface. The replica transimpedance stage may have an input that is coupled to an output of the replica transimpedance stage.

The calibration circuit may further have a comparison circuit that is configured to generate a difference signal representative of a difference between voltage levels of an input signal received at an input of the replica transconductance stage and an output signal representative of voltage level at the output of the replica transimpedance stage.

The calibration circuit may further have replica feedback resistors configured to couple an output of the replica transimpedance stage to the input of the replica transconductance stage. The difference signal may be used to configure, adjust or select resistance values provided by the replica feedback resistors. The difference signal may be used to configure, adjust or select resistance values provided by corresponding gain control resistors in the transimpedance amplifier in the SerDes interface. The calibration circuit may be configured such that the gain control resistors have the same resistance values as the replica feedback resistors. The gain control resistors may be configured to control gain provided by the transimpedance amplifier in the SerDes interface. In some examples, the gain control resistors are configured to couple outputs and inputs of the transimpedance amplifier in the SerDes interface.

In certain implementations, the voltage level at the input of the replica transconductance stage is determined by a common mode voltage level at an input of the transconductance amplifier in the SerDes interface. In one example, the voltage level at the input of the replica transconductance stage is about 50 millivolts or less.

In some implementations, the calibration circuit has a multitap resistance bridge and one or more multiplexers. The multitap resistance bridge may be configured to receive a first signal from the output of the replica transimpedance stage. The one or more multiplexers configured to select between the first signal and one or more attenuated versions of the first signal provided by the multitap resistance bridge in order to provide the output signal representative of voltage level at the output of the replica transimpedance stage. In some examples, the taps of the multitap resistance bridge are configured to correspond to gain settings defined for a gₘ-TIA gain stage that includes the transconductance amplifier and the transimpedance amplifier. In some examples, the taps of the multitap resistance bridge are configured to provide gain levels defined for a gₘ-TIA gain stage that includes the transconductance amplifier and the transimpedance amplifier.

Some implementation examples are described in the following numbered clauses:
1. A calibration circuit, comprising: a replica transconductance stage that is a replica of a transconductance amplifier (“gₘ”) in a serializer/deserializer (SerDes) interface; a replica transimpedance stage that is a replica of a transimpedance amplifier (“TIA”) in the SerDes interface, the replica transimpedance stage having an input that is coupled to an output of the replica transimpedance stage; a comparison circuit configured to generate a difference signal representative of a difference between voltage levels of an input signal received at an input of the replica transconductance stage and an output signal representative of voltage level at the output of the replica transimpedance stage; and replica feedback resistors configured to couple an output of the replica transimpedance stage to the input of the replica transconductance stage.
2. The calibration circuit as described in clause 1, wherein the difference signal is used to select resistance values provided by the replica feedback resistors and by corresponding gain control resistors in the transimpedance amplifier in the SerDes interface.
3. The calibration circuit as described in clause 1 or clause 2, wherein the gain control resistors are configured to control gain provided by the transimpedance amplifier in the SerDes interface.
4. The calibration circuit as described in any of clauses 1-3, wherein the gain control resistors are configured to couple outputs and inputs of the transimpedance amplifier in the SerDes interface.
5. The calibration circuit as described in any of clauses 1-4, wherein the voltage level at the input of the replica transconductance stage is determined by a common mode voltage level at an input of the transconductance amplifier in the SerDes interface.
6. The calibration circuit as described in any of clauses 1-5, wherein the voltage level at the input of the replica transconductance stage is about 50 millivolts or less.
7. The calibration circuit as described in any of clauses 1-6, further comprising: a multitap resistance bridge configured to receive a first signal from the output of the replica transimpedance stage; and one or more multiplexers configured to select between the first signal and one or more attenuated versions of the first signal provided by the multitap resistance bridge in order to provide the output signal representative of voltage level at the output of the replica transimpedance stage.
8. The calibration circuit as described in clause 7, wherein taps of the multitap resistance bridge correspond to gain settings defined for a gₘ-TIA gain stage that includes the transconductance amplifier and the transimpedance amplifier.
9. An apparatus, comprising: a replica transconductance stage that is a replica of a transconductance amplifier (“gm”) in a serializer/deserializer (SerDes) interface; a replica transimpedance stage that is a replica of a transimpedance amplifier (“TIA”) in the SerDes interface, the replica transimpedance stage having an input that is coupled to an output of the replica transimpedance stage; means for comparing voltage levels, configured to generate a difference signal representative of a voltage difference between an input signal received at an input of the replica transconductance stage and an output signal representative of voltage level at the output of the replica transimpedance stage; and means for controlling gain of a gm-TIA gain stage that includes the transconductance amplifier and the transimpedance amplifier, including gain control resistors configured to couple outputs and inputs of the transimpedance amplifier, means for configuring replica feedback resistors that couple an output of the replica transimpedance stage to the input of the replica transconductance stage, wherein the difference signal is used by the means for configuring the replica feedback resistors to minimize or reduce the voltage difference between the input signal and the output signal.
10. The apparatus as described in clause 9, wherein the difference signal is used by the means for controlling the gain of the gm-TIA gain stage by causing the gain control resistors to have the same resistance values as the replica feedback resistors.
11. The apparatus as described in clause 9 or clause 10, wherein the gain control resistors are configured to couple outputs and inputs of the transimpedance amplifier in the SerDes interface.
12. The apparatus as described in any of clauses 9-11, wherein the voltage level at the input of the replica transconductance stage is determined by a common mode voltage level at an input of the transconductance amplifier in the SerDes interface.
13. The apparatus as described in any of clauses 9-12, wherein the voltage level at the input of the replica transconductance stage is about 50 millivolts or less.
14. The apparatus as described in any of clauses 9-13, further comprising: means for obtaining one or more attenuated versions of a first signal received from the output of the replica transimpedance stage; and means for selecting between the first signal and the one or more attenuated versions of the first signal in order to provide the output signal representative of voltage level at the output of the replica transimpedance stage.
15. The apparatus as described in clause 14, wherein the means for obtaining the one or more attenuated versions of the first signal includes a multitap resistance bridge, and wherein taps of the multitap resistance bridge correspond to gain settings defined for a gm-TIA gain stage that includes the transconductance amplifier and the transimpedance amplifier.
16. A method for calibrating gain, comprising: providing a direct current (DC) input signal to an input of a replica transconductance stage that is a replica of a transconductance amplifier (“gm”) in a serializer/deserializer (SerDes) interface; coupling an output of the replica transconductance stage to an input of a replica transimpedance stage that is a replica of a transimpedance amplifier (“TIA”) in the SerDes interface; generating a difference signal representative of a voltage difference between the DC input signal an output signal representative of voltage level at the output of the replica transimpedance stage; using the difference signal to minimize or reduce the voltage difference by configuring resistance values for replica feedback resistors that couple an output of the replica transimpedance stage to the input of the replica transconductance stage; and using the difference signal to configure gain control resistors in the transimpedance amplifier in the SerDes interface such that the gain control resistors have the same resistance values as the replica feedback resistors.
17. The method as described in clause 16, wherein the gain control resistors are configured to control gain provided by the transimpedance amplifier in the SerDes interface.
18. The method as described in clause 16 or clause 17, wherein the gain control resistors are configured to couple outputs and inputs of the transimpedance amplifier in the SerDes interface.
19. The method as described in any of clauses 16-18, wherein the voltage level at the input of the replica transconductance stage is determined by a common mode voltage level at an input of the transconductance amplifier in the SerDes interface.
20. The method as described in any of clauses 16-19, wherein the voltage level at the input of the replica transconductance stage is about 50 millivolts or less.
21. The method as described in any of clauses 16-20, further comprising: attenuating a first signal received from the output of the replica transimpedance stage to obtain one or more attenuated versions of the first signal; and selecting between the first signal and the one or more attenuated versions of the first signal in order to provide the output signal representative of voltage level at the output of the replica transimpedance stage.
22. The method as described in clause 21, wherein the first signal is attenuated using a multitap resistance bridge, and wherein taps of the multitap resistance bridge correspond to gain settings defined for a gₘ-TIA gain stage that includes the transconductance amplifier and the transimpedance amplifier.

As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

The present disclosure is provided to enable any person skilled in the art to make or use aspects of the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein, but is to be accorded the widest scope consistent with the principles and novel features disclosed herein.

What is claimed is:

1. A calibration circuit, comprising:
a replica transconductance stage that is a replica of a transconductance amplifier (“gm”) in a serializer/deserializer (SerDes) interface;
a replica transimpedance stage that is a replica of a transimpedance amplifier (“TIA”) in the SerDes interface, the replica transimpedance stage having an input that is coupled to an output of the replica transimpedance stage;
a comparison circuit configured to generate a difference signal representative of a difference between voltage levels of an input signal received at an input of the replica transconductance stage and an output signal representative of voltage level at the output of the replica transimpedance stage; and
replica feedback resistors configured to couple an output of the replica transimpedance stage to the input of the replica transconductance stage.

2. The calibration circuit of claim 1, wherein the difference signal is used to select resistance values provided by the replica feedback resistors and by corresponding gain control resistors in the transimpedance amplifier in the SerDes interface.

3. The calibration circuit of claim 1, wherein the gain control resistors are configured to control gain provided by the transimpedance amplifier in the SerDes interface.

4. The calibration circuit of claim 1, wherein the gain control resistors are configured to couple outputs and inputs of the transimpedance amplifier in the SerDes interface.

5. The calibration circuit of claim 1, wherein the voltage level at the input of the replica transconductance stage is determined by a common mode voltage level at an input of the transconductance amplifier in the SerDes interface.

6. The calibration circuit of claim 1, wherein the voltage level at the input of the replica transconductance stage is about 50 millivolts or less.

7. The calibration circuit of claim 1, further comprising:
a multitap resistance bridge configured to receive a first signal from the output of the replica transimpedance stage; and
one or more multiplexers configured to select between the first signal and one or more attenuated versions of the first signal provided by the multitap resistance bridge in order to provide the output signal representative of voltage level at the output of the replica transimpedance stage.

8. The calibration circuit of claim 7, wherein taps of the multitap resistance bridge correspond to gain settings defined for a gm-TIA gain stage that includes the transconductance amplifier and the transimpedance amplifier.

9. An apparatus, comprising:
a replica transconductance stage that is a replica of a transconductance amplifier (“gm”) in a serializer/deserializer (SerDes) interface;
a replica transimpedance stage that is a replica of a transimpedance amplifier (“TIA”) in the SerDes interface, the replica transimpedance stage having an input that is coupled to an output of the replica transimpedance stage;
means for comparing voltage levels, configured to generate a difference signal representative of a voltage difference between an input signal received at an input of the replica transconductance stage and an output signal representative of voltage level at the output of the replica transimpedance stage; and
means for controlling gain of a gm-TIA gain stage that includes the transconductance amplifier and the transimpedance amplifier, including gain control resistors configured to couple outputs and inputs of the transimpedance amplifier,
means for configuring replica feedback resistors that couple an output of the replica transimpedance stage to the input of the replica transconductance stage,
wherein the difference signal is used by the means for configuring the replica feedback resistors to minimize or reduce the voltage difference between the input signal and the output signal.

10. The apparatus of claim 9, wherein the difference signal is used by the means for controlling the gain of the gm-TIA gain stage by causing the gain control resistors to have the same resistance values as the replica feedback resistors.

11. The apparatus of claim 9, wherein the gain control resistors are configured to couple outputs and inputs of the transimpedance amplifier in the SerDes interface.

12. The apparatus of claim 9, wherein the voltage level at the input of the replica transconductance stage is determined by a common mode voltage level at an input of the transconductance amplifier in the SerDes interface.

13. The apparatus of claim 9, wherein the voltage level at the input of the replica transconductance stage is about 50 millivolts or less.

14. The apparatus of claim 9, further comprising:
means for obtaining one or more attenuated versions of a first signal received from the output of the replica transimpedance stage; and
means for selecting between the first signal and the one or more attenuated versions of the first signal in order to provide the output signal representative of voltage level at the output of the replica transimpedance stage.

15. The apparatus of claim 14, wherein the means for obtaining the one or more attenuated versions of the first signal includes a multitap resistance bridge, and wherein taps of the multitap resistance bridge correspond to gain settings defined for a gm-TIA gain stage that includes the transconductance amplifier and the transimpedance amplifier.

16. A method for calibrating gain, comprising:
providing a direct current (DC) input signal to an input of a replica transconductance stage that is a replica of a transconductance amplifier (“gm”) in a serializer/deserializer (SerDes) interface;
coupling an output of the replica transconductance stage to an input of a replica transimpedance stage that is a replica of a transimpedance amplifier (“TIA”) in the SerDes interface;
generating a difference signal representative of a voltage difference between the DC input signal an output signal representative of voltage level at the output of the replica transimpedance stage;
using the difference signal to minimize or reduce the voltage difference by configuring resistance values for replica feedback resistors that couple an output of the replica transimpedance stage to the input of the replica transconductance stage; and
using the difference signal to configure gain control resistors in the transimpedance amplifier in the SerDes interface such that the gain control resistors have the same resistance values as the replica feedback resistors.

17. The method of claim 16, wherein the gain control resistors are configured to couple outputs and inputs of the transimpedance amplifier in the SerDes interface and are further configured to control gain provided by the transimpedance amplifier in the SerDes interface.

18. The method of claim 16, wherein the voltage level at the input of the replica transconductance stage is about 50 millivolts or less and is determined by a common mode voltage level at an input of the transconductance amplifier in the SerDes interface.

19. The method of claim 16, further comprising:
attenuating a first signal received from the output of the replica transimpedance stage to obtain one or more attenuated versions of the first signal; and
selecting between the first signal and the one or more attenuated versions of the first signal in order to provide the output signal representative of voltage level at the output of the replica transimpedance stage.

20. The method of claim 19, wherein the first signal is attenuated using a multitap resistance bridge, and wherein taps of the multitap resistance bridge correspond to gain settings defined for a gm-TIA gain stage that includes the transconductance amplifier and the transimpedance amplifier.
